(19) United States
(12) Patent Application Publication
(10) Pub. No.: US 2011/0262650 A1
(43) Pub. Date: Oct. 27, 2011

(54) VAPORIZING OR ATOMIZING OF ELECTRICALLY CHARGED DROPLETS

(75) Inventor: Sang In LEE, Sunnyvale, CA (US)

(73) Assignee: SYNOS TECHNOLOGY, INC., Sunnyvale, CA (US)

(21) Appl. No.: 13/094,637

(22) Filed: Apr. 26, 2011

Related U.S. Application Data
(60) Provisional application No. 61/328,512, filed on Apr. 27, 2010.

(51) Int. Cl. C23C 16/44; B05C 11/00; H05B 3/03; B05D 1/00; B05D 1/32; B05C 5/00; B05B 1/00

(52) U.S. Cl. 427/457; 118/723 R; 118/620; 219/482

(57) ABSTRACT

A vaporizing apparatus includes a chamber, a nozzle for dispersing a liquid into droplets, an electrode electrically isolated from the nozzle, and a heater for generating a vapor by applying heat to the droplets. The voltage source applies charges to the droplets by applying a voltage between the nozzle and the electrode. The vaporizing apparatus may be used to devices that deposit organic or inorganic thin films by chemical vapor deposition and/or atomic layer deposition processes, devices for supplying precursor materials that are deposited to form a thin film in organic light emitting diodes, devices that supply organic or inorganic precursor materials for encapsulation, and devices for supplying organic or inorganic polymer.

### CROSS-REFERENCE TO RELATED APPLICATION

This application claims priority under 35 U.S.C. §119(e) to co-pending U.S. Provisional Patent Application No. 61/328,512, filed on Apr. 27, 2010, which is incorporated by reference herein in its entirety.

### BACKGROUND

1. Field of Art

The present invention relates to a vaporizing apparatus and a vaporizing method, more particularly to an apparatus and a method for vaporizing liquid for use in semiconductor fabrication processes.

2. Description of the Related Art

High performance fluid delivery systems are employed in semiconductor manufacturing processes. Such fluid delivery systems are designed to precisely dispense fluids that are hazardous and/or expensive. For example, in semiconductor fabrication processes, various stages such as low pressure chemical vapor deposition (LPCVD), oxidation, plasma enhanced chemical vapor deposition (PECVD), and atomic layer deposition (ALD) require corrosive precursors such as boron, silicon and phosphorous to be delivered to a wafer processing chamber to manufacture semiconductor devices.

Atomizing and/or vaporizing of a liquid is often necessary in fluid processing applications. For example, these processes may be employed to deposit an organic or inorganic thin film on semiconductor devices using chemical vapor deposition (CVD) and/or ALD processes. FIG. 1A is a schematic diagram illustrating a conventional vaporizer in a semiconductor fabrication device. The vaporizer receives a carrier gas and a liquid fluid via a mass flow controller (MFC) 101 and a liquid flow meter (LFM) 102, respectively. The vaporizer 103 vaporizes the liquid fluid by dropping the pressure and mixing the vapor with the carrier gas for transfer to a destination field-of-use device.

FIG. 1B is a schematic diagram of a conventional vaporizing system. The vaporizing system includes a liquid tank 103, LFM 102, MFC 101, a piezo-valve 104, a valve controller 105, heater controllers 106, and a vaporizer 107. A liquid fluid (precursor) is supplied from the liquid tank 103 by injecting a helium gas to the liquid tank. The liquid fluid is conveyed to the piezo-valve 104 via LFM 102 that controls the flow rate of the liquid fluid. Similarly, the flow rate of the carrier gas to the piezo-valve 104 is controlled by MFC 102. The piezo-valve 104 has a mechanism that oscillates according to a signal from the valve controller 105 to combine the precursor and carrier gas. The combined mixture of the precursor and the carrier gas is vaporized at the vaporizer 107. The vaporizer 107 may include a nozzle 1071 for dropping the pressure of the mixture and a heater 1072 for increasing the temperature of the mixture.

FIG. 2A is a phase diagram illustrating phases of matter at different pressure and temperature points. As illustrated in FIG. 2A, a liquid may be transformed to a gas by either dropping the pressure (represented by a solid arrow) or increasing the temperature (represented by a dashed arrow). Increasing the temperature to change the phase may take an extended amount of time depending on the specific heat of the liquid fluid, and hence, rapid vaporization is difficult to achieve by increasing the temperature in certain types of liquid. In contrast, the pressure of a liquid can be dropped instantaneously using Venturi effect. Hence, dropping the pressure of a liquid, sometimes in combination with heating of the liquid, is often used to vaporize a liquid.

FIG. 2B is a cross-sectional diagram of a conventional vaporizer 200 consisting of an atomizing stage 2000 and a vaporizing stage 2100. In order to effectuate Venturi effect, a mixture of carrier gas and liquid droplets passes through a nozzle with diameter dᵢ in the atomizing stage 2000. Then the mixture enters a wider area with diameter dₒ. The ratio R defined as dᵢ/dₒ generally is in the range of 10 to 20. By increasing R value, smaller droplets can be obtained by Venturi effect. A heater 201 is provided in the vaporizer 200 to heat the droplets at the vaporizing stage 2100.

The vaporizer of FIG. 2B, however, has following disadvantages: (i) precursor with high viscosity or low vapor-pressure tend to clog the nozzle, (ii) the droplets formed in the atomizing stage are uneven in size, and hence, the vaporization stage produces some liquid droplets that are not vaporized, and (iii) the droplets may come in contact with the interior wall of the vaporizer and scorch or clog the wall.

### SUMMARY

Embodiments relate to forming droplets of small size by electrically charging the droplets. Liquid is injected into a nozzle that is connected to a voltage source. As the liquid passes through the nozzle, the liquid or droplets are electrically charged. When charges in a droplet exceed a threshold, the droplet divides into multiple droplets. Hence, droplets of smaller sizes are obtained at the nozzle by charging the droplets. Moreover, the droplets charged with the same polarity repel each other, resulting in more even and uniformly dispersed droplets.

### BRIEF DESCRIPTION OF DRAWINGS

FIG. 1A is a schematic diagram illustrating a conventional vaporizer in a semiconductor fabrication device.

FIG. 1B is a schematic diagram of a conventional vaporizing system.

FIG. 2A is a phase diagram illustrating phases of matter at different pressures and temperatures.

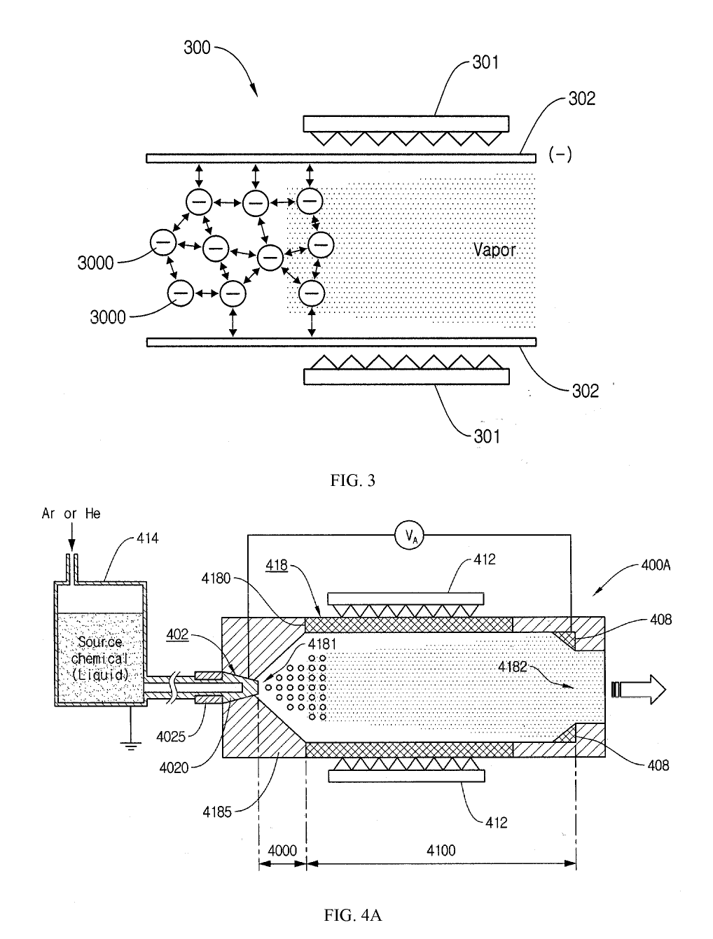

FIG. 2B is a cross-sectional diagram of a conventional vaporizer consisting of an atomizing stage and a vaporizing stage.

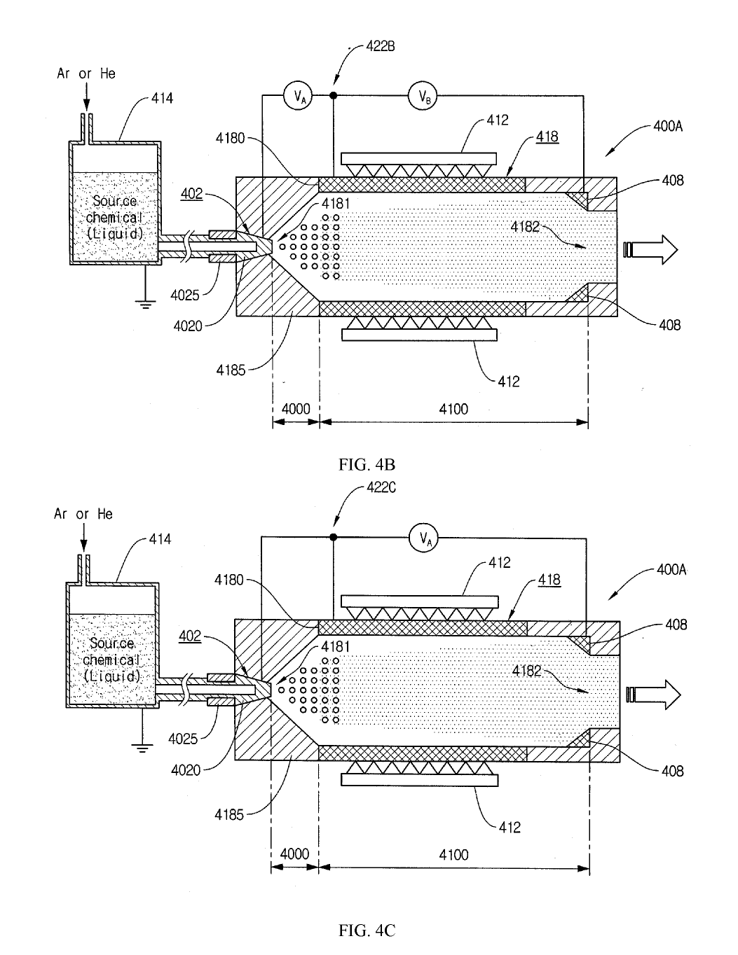

FIG. 3 is a schematic diagram illustrating the principle of a vaporizer according to an embodiment.

FIGS. 4A through 4D are diagrams illustrating a vaporizing apparatus, according to embodiments.

FIGS. 5A through 5I are various example voltage signals which may be applied to a vaporizing apparatus, according to embodiments.

FIGS. 6A through 6C are block diagrams of a vaporizing apparatus according to embodiments.

FIG. 7A is a diagram illustrating an example where a vapor is not completely neutralized in a vaporizing apparatus, according to an embodiment.

FIG. 7B is a diagram illustrating an example where a vapor is completely neutralized in a vaporizing apparatus, according to an embodiment.

FIG. 8 is a schematic diagram illustrating an atomic layer deposition (ALD) device incorporating a vaporizing apparatus, according to an embodiment.

FIG. 9 is a schematic diagram illustrating another ALD device incorporating a vaporizing apparatus, according to an embodiment.

FIG. 10 is a flowchart illustrating a method of vaporizing a liquid, according to an embodiment.

FIG. 11A is a schematic diagram illustrating ejecting of charged droplets or vapor onto a substrate partially covered with a shadow mask, according to one embodiment.

FIG. 11B is a schematic diagram illustrating ejecting of charged droplets or vapor onto a substrate partially covered with a shadow mask, according to another embodiment.

FIG. 12 is a flowchart illustrating a method of ejecting charged droplets or vapor onto a substrate using a shadow mask, according to one embodiment.

### DETAILED DESCRIPTION OF EMBODIMENTS

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments.

The terminology used herein is for the purpose of describing particular exemplary embodiments only and is not intended to be limiting of this disclosure. As used herein, the singular forms “a”, “an” and “the” are intended to include the plural forms as well, unless the context clearly indicates otherwise. Furthermore, the use of the terms a, an, etc. does not denote a limitation of quantity, but rather denotes the presence of at least one of the referenced item. The use of the terms “first”, “second”, and the like does not imply any particular order, but they are included to identify individual elements. Moreover, the use of the terms first, second, etc. does not denote any order or importance, but rather the terms first, second, etc. are used to distinguish one element from another. It will be further understood that the terms “comprises” and/or “comprising”, or “includes” and/or “including” when used in this specification, specify the presence of stated features, regions, integers, steps, operations, elements, and/or components, but do not preclude the presence or addition of at least one other features, regions, integers, steps, operations, elements, components, and/or groups thereof.

In the drawings, like reference numerals in the drawings denote like elements. The shape, size and regions, and the like, of the drawing may be exaggerated for clarity.

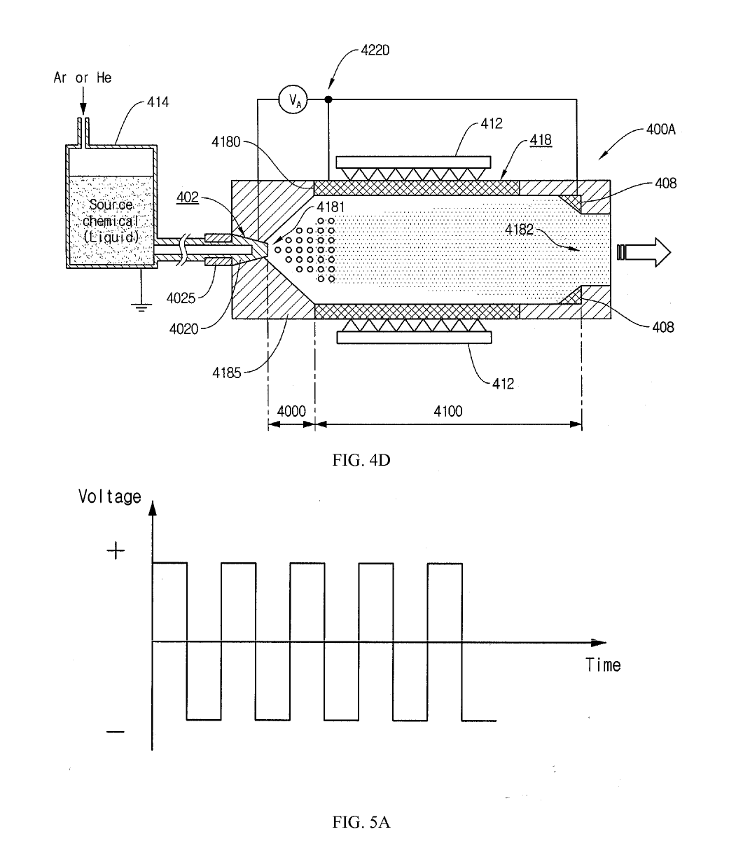

FIG. 3 is a schematic diagram illustrating the principle of a vaporizer according to an embodiment. A liquid is atomized into one or more droplets 3000 in a vaporizer 300. As the liquid is atomized into the one or more droplets 3000, the droplets 3000 are electrically charged. Each of the droplets 3000 may be charged above a threshold level. A droplet 3000 may hold a certain amount of charges beyond which the droplet 3000 divides up into multiple droplets. The threshold level may be such that the droplets initially produced through Ventury effect are further atomized into smaller droplets. The droplets 3000 are charged to have the same polarity. For example, all the droplets 3000 may be negatively charged, but without being limited thereto. Since the droplets 3000 are charged to have the same polarity, repulsive force causes the droplets to divide into smaller droplets as well as spread the distance between the droplets 3000. As a result, the droplets initially produced may be further atomized into fine and even sized droplets 3000.

In an embodiment, a voltage may be applied to an interior wall 302 of the vaporizer 300. For example, a voltage of the same polarity as that of the charge in the droplets 3000 is applied to the interior wall 302 of the vaporizer 300. When the voltage potential of the interior wall 302 has the same polarity as that of the charge in the droplets 3000, repulsion may occur between the droplets 3000 and the interior wall 302. The repulsion prevents the droplets 3000 from contacting the interior wall 302 of the vaporizer 300, and thereby prevents scorching or clogging of the interior wall 302 by the droplets 3000.

However, this is only exemplary, and a voltage of the polarity different from that of the charge of the droplets 3000 may be applied to the interior wall 302 of the vaporizer 300 in another embodiment.

The size of each droplet 3000 and the distance between the droplets 3000 are determined at least in part based on the amount of charges applied to the droplets 3000. The droplets 3000 are charged by applying a voltage along the trajectory of the droplets 3000 in the vaporizer 300. The amount of the charges applied to the droplets 3000 may be determined at least in part based on the amplitude of the voltage applied along the trajectory of the droplets 3000.

The charged droplets 3000 may be heated by a heater 301 to vaporize the droplets 3000. The vaporization of the droplets 3000 is accomplished more easily with smaller sized droplets 3000. In this regard, the embodiment of FIG. 3 is advantageous over conventional vaporization technique, since the droplets 3000 have a relatively smaller size due to the electrostatic repulsion. The formed vapor may be expanded to fill the space inside the interior wall 302 of the vaporizer 300.

In FIG. 3, the droplets 3000 are shown to be negatively charged. However, this is merely exemplary, and the droplets 3000 may be positively charged in other embodiments. In still another embodiment, the polarity of the voltage applied to charge the droplets 3000 may vary with time. For example, an alternating current (AC) voltage signal having positive and negative voltage potentials may be applied. By vaporizing the droplets 3000 charged by the AC voltage, positively charged vapor and negatively charged vapor may be generated in an alternating manner. The produced positively charged vapor and negatively charged vapor may be mixed with each other to neutralized the charge of the vapor.

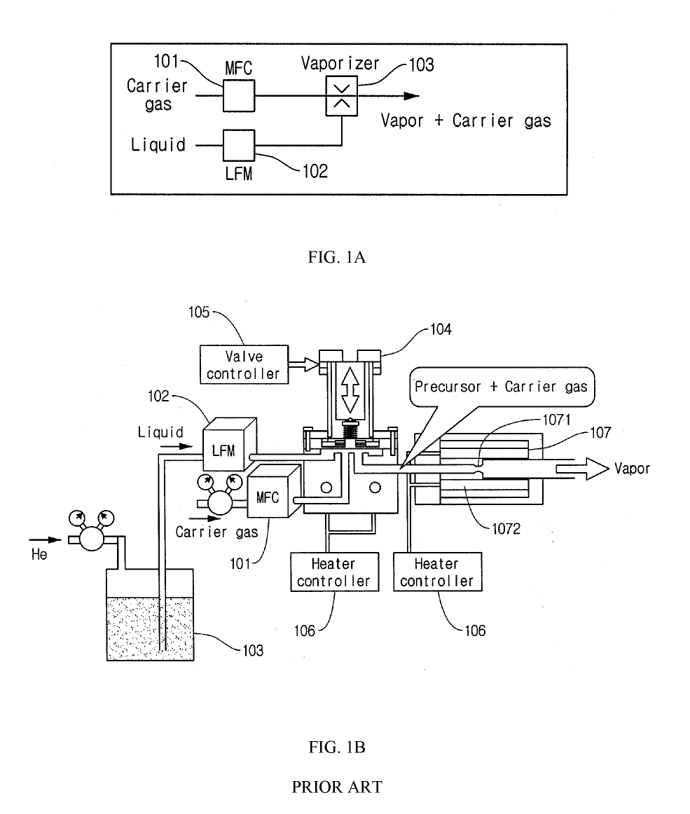

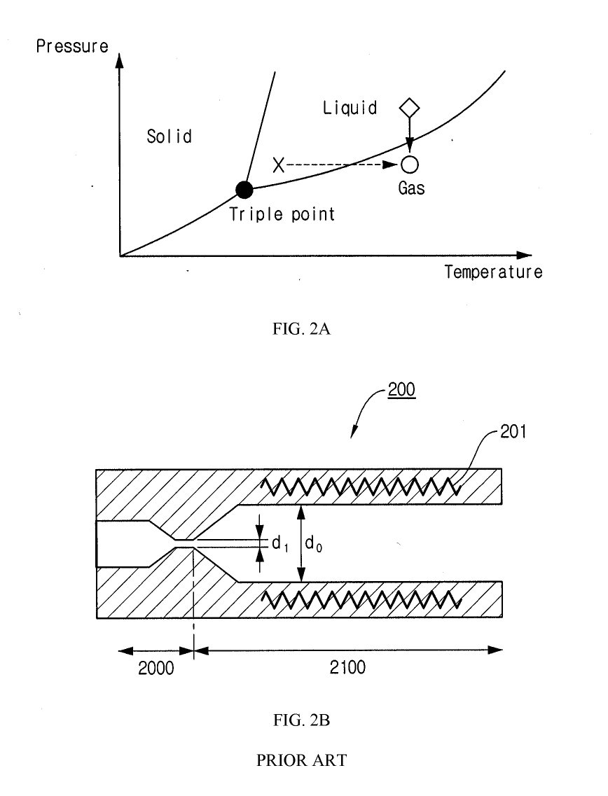

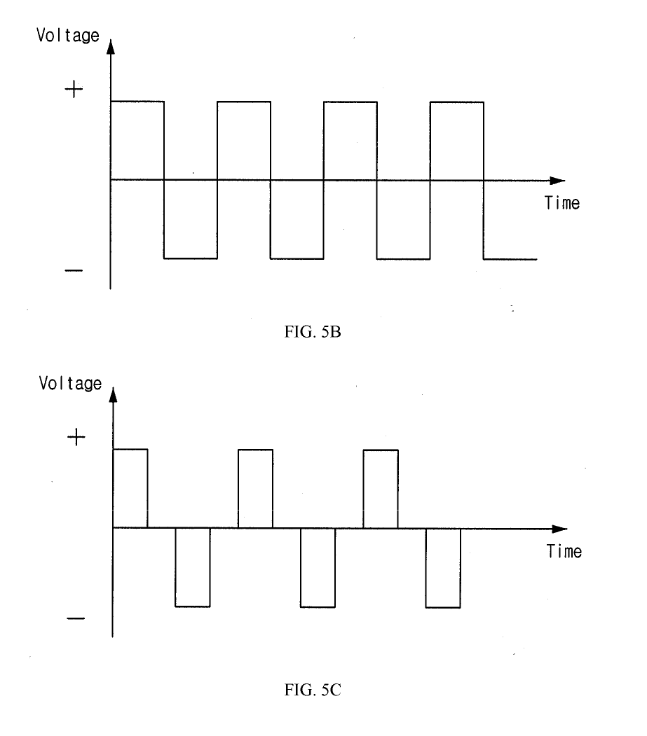

FIG. 4A is a diagram illustrating a vaporizing apparatus according to an embodiment. A vaporizing apparatus may include a vaporizer 400A and a voltage source V_{A}. The vaporizer 400A may include a chamber 418, a nozzle 402, an electrode 408, and a heater 412. The vaporizing apparatus may further include a source tank 414 for storing the liquid to be vaporized and/or a carrier gas tank (not shown) for storing a carrier gas. In addition, the vaporizing apparatus may further include a liquid flow meter (LFM) (not shown) for controlling the flow rate of the source liquid, a mass flow controller (MFC) (not shown) for controlling the flow rate of the carrier gas, or the like. The functions of the source tank 414, the carrier gas tank, the LFM, the MFC are similar to counterpart components in FIG. 1B, and thus, will not be described in detail.

In the vaporizing apparatus shown in FIG. 4A, the vaporizer 400A may be functionally divided into an atomizing stage 4000 and a vaporizing stage 4100. In the atomizing stage 4000, the liquid and the carrier gas are sprayed into the chamber 418 via the nozzle 402. The chamber 418 may have a cylindrical shape or other adequate shapes. The nozzle 402 may be attached to one side of the chamber 418. Through the nozzle 402, the liquid and the carrier gas are sprayed into the chamber 418. The sprayed liquid is atomized into a plurality of droplets due to Venturi effect caused by the pressure difference inside the nozzle 402 and outside the nozzle 402.

The nozzle 402 may include at least in part a conducting material. The nozzle 402 may include a first portion 4020 made of a conducting material such as metal and a second portion 4025 made of an insulating material such as ceramic. Using the first portion (conducting material) 4020 of the nozzle 402 charges are applied to the droplets of the liquid passing through the first portion 4020 and sprayed into the chamber 418. As described above with reference to FIG. 3, the charged droplets may have a smaller and more uniform size than the droplets initially formed by Venturi effect, facilitating vaporization in the following process.

In the vaporizing stage 4100, the droplets generated and charged in the atomizing stage 4000 are vaporized by heat applied by the heater 412. The chamber 418 has an interior wall 4180 made of a thermally conductive material such as stainless steel. For example, the interior wall 4180 has a cylindrical shape. The heater 412 heats the interior wall 4180 to vaporize the droplets in the chamber 418. In the chamber 418, the remaining portion 4185 excluding the interior wall 4180 is made of, for example, a ceramic material.

The chamber 418 includes the electrode 408 that is electrically isolated from the nozzle 402. For example, the electrode 408 is disposed at the opposite side of the nozzle 402. The electrode 408 may be made of a conducting material such as metal. The voltage source V_{A} applies a voltage across the nozzle 402 and the electrode 408. For example, the voltage source V_{A} applies a first voltage to the first portion 4020 of the conductive nozzle 402 and applies a second voltage to the electrode 408. A voltage corresponding to the difference between the first voltage and the second voltage is applied to the space between the nozzle 402 and the electrode 408, and charges may be applied to the droplets by this voltage. The voltage applied by the voltage source V_{A} may be either a direct current (DC) signal or an alternating current (AC) signal.

The chamber 418 has a first hole 4181 connected to the nozzle 402 through which the liquid and the carrier gas are sprayed. The chamber 418 may further have a second hole 4182 through which the vapor and the carrier gas are discharged from the chamber. By discharging the vapor through the second hole 4182, the vapor generated by the vaporizer 400A may be supplied to various devices requiring the vapor, such as a vapor reservoir, a reactor, an injector, a nozzle or a showerhead-type device.

In an embodiment, depending on the type of the voltage applied by the voltage source V_{A}, the vapor outlet from the vaporizer 400A may be charged. For example, the voltage source V_{A} applies an AC voltage signal having alternating positive and negative values, and positively charged vapor and negatively charged vapor may be generated in an alternating manner from the vaporizer 400A. By controlling the AC voltage signal and/or controlling the flow rate of the carrier gas, a polarity of the vapor finally output from the vaporizing apparatus may be controlled.

In an embodiment, the polarity of the vapor may be controlled by controlling the frequency, pulse width, polarity, duty cycle, etc. of the AC voltage signal. For example, the frequency, pulse width, polarity, duty cycle, etc. of the AC voltage signal may be determined at least in part based on the flow rate of the carrier gas carrying the droplets of the liquid, the size of each portion of the chamber 418, retention time of the droplets in the atomizing stage 4000 or the vaporizing stage 4100, and so forth.

For example, the flow rate of the carrier gas may be about 10 m/sec. And, the atomizing stage 4000 of the vaporizer 400A may be about 2 cm in length. The length of the atomizing stage 4000 refers to the distance between the nozzle 402 and the interior wall 4180 along the trajectory of the liquid and the carrier gas. Also, in the vaporizer 400A, the vaporizing stage 4100 may be about 5 cm in length. The length of the vaporizing stage refers to the distance from the start of the interior wall 4180 to the end of the electrode 408 along the trajectory of the liquid and the carrier gas.

In this particular example, the time required for the droplets of the liquid to pass through the atomizing stage 4000 is about 2 msec (2 cm divided by 10 m/sec), and the time required for the droplets to pass through the vaporizing stage 4100 is about 5 msec (5 cm divided by 10 m/sec). Suppose that the voltage applied by the voltage source V_{A} is an AC voltage signal alternating to have positive (+) and negative (−) values with a duty cycle of about 50%, the polarity of the charges applied to the droplets also alternates between positive potential and negative potential. Unless the time interval between the time section where positive charges are applied to the droplets and the time section where negative charges are applied to the droplets is sufficiently large, the droplets of opposite polarity may cluster in the atomizing stage 4000 to form larger droplets.

However, if the pulse width of the AC voltage signal is about 2 msec or longer (if frequency is 250 Hz or lower), droplets with opposite polarity do not exist in the atomizing stage 4000. But, if the pulse width of the voltage signal is about 5 msec or shorter (if frequency is 100 Hz or higher), droplets with opposite polarity may exist as vapor in the vaporizing stage 4100. Accordingly, in order to prevent the droplets with opposite polarity from existing both in the atomizing stage and the vaporizing stage, the frequency of the voltage signal applied from the voltage source V_{A} may be determined to be about 100 Hz or lower. However, this is only exemplary, and the frequency of the voltage signal applied by the voltage source V_{A} is not limited to the frequency range for preventing the droplets or vapor with opposite polarity from coming into contact with each other.

FIG. 4B is a diagram illustrating a vaporizing apparatus according to another embodiment. In the following description, Figures are described focusing mainly on the differences from the embodiment of FIG. 4A. The vaporizing apparatus of FIG. 4B includes a first voltage source V_{A} and a second voltage source V_{B} as voltage sources. In the vaporizer 4000A, an interior wall 4180 of a chamber 418 is made of a conducting material and is electrically connected to a node 422B between the first voltage source V_{A} and the second voltage source V_{B}. As a result, the first voltage source V_{A} applies a voltage across a nozzle 402 and the interior wall 4180, and the second voltage source V_{B} applies a voltage across the interior wall 4180 and an electrode 408.

In an embodiment, a first voltage may be applied to the nozzle 402, a second voltage may be applied to the electrode 408, and a third voltage may be applied to the interior wall 4180. The first voltage, the second voltage and the third voltage may be different from one another. For example, the first voltage source V_{A} applies a relatively low first voltage to the nozzle 402 and a relatively high third voltage to the interior wall 4180. And, the second voₗtage source V_{B} may apply a second voltagₑ which is lower than the third voltage to the electrode 408. However, this is only exemplary, and the amplitude of the first voltage, the second voltage and the third voltage may be determined adequately based on the viscosity of the liquid, the amount of charges that can be applied, the vapor pressure inside the apparatus, or various other factors.

For example, a negative voltage may be applied to the nozzle 402 and the droplets sprayed through the nozzle 402 may be negatively charged. In this case, by applying a positive voltage to the interior wall 4180, the negatively charged droplets may be accelerated toward a second hole 4182 of the chamber 418. Also, a negative voltage may be applied to the electrode 408 so as to reduce or prevent the contact of vapor generated from the negatively charged droplets to the electrode 408. However, this is only exemplary. In another embodiment, a voltage of the same polarity as the charge of the droplets may be applied to the interior wall 4180 so as to reduce or prevent the contact of the droplets with the surface of the interior wall 4180.

In an embodiment, the difference of the voltages applied to both ends of the first voltage source V_{A} (i.e., the difference of the first voltage and the third voltage) may be about 1 kV. In this case, the difference of the voltages applied to both ends of the second voltage source V_{B} (i.e., the difference of the second voltage and the third voltage) may be not greater than 1 kV, but without being limited thereto. The voltages applied to the both ends of the first voltage source V_{A} and the second voltage source V_{B} may be controlled adequately based on factors such as the flow rate of a carrier gas in the vaporizer 4000A and permissible minimum droplet size.

FIG. 4C is a diagram illustrating a vaporizing apparatus according to another embodiment. A voltage source V_{A} may apply a voltage between a nozzle 402 and an electrode 408. The nozzle 402 and an interior wall 4180 may be electrically connected to each other. For example, the nozzle 402 and the interior wall 4180 is commonly connected to a node 422C at one end of the voltage source V_{A}. The voltage source V_{A} applies a first voltage to the nozzle 402 and the interior wall 4180 and may apply a second voltage to the electrode 408. The advantage resulting from the application of the voltage to the interior wall 4180 will be easily understood from the foregoing embodiment described with reference to FIG. 4B.

FIG. 4D is a diagram illustrating a vaporizing apparatus according to another embodiment. A voltage source V_{A} applies a voltage between a nozzle 402 and an electrode 408. The electrode 408 and an interior wall 4180 may be connected electrically to each other. For example, the electrode 408 and the interior wall 4180 is commonly connected to a node 422D at one end of the voltage source V_{A}. The voltage source V_{A} applies a first voltage to the nozzle 402 and applies a second voltage to the interior wall 4180 and the electrode 408.

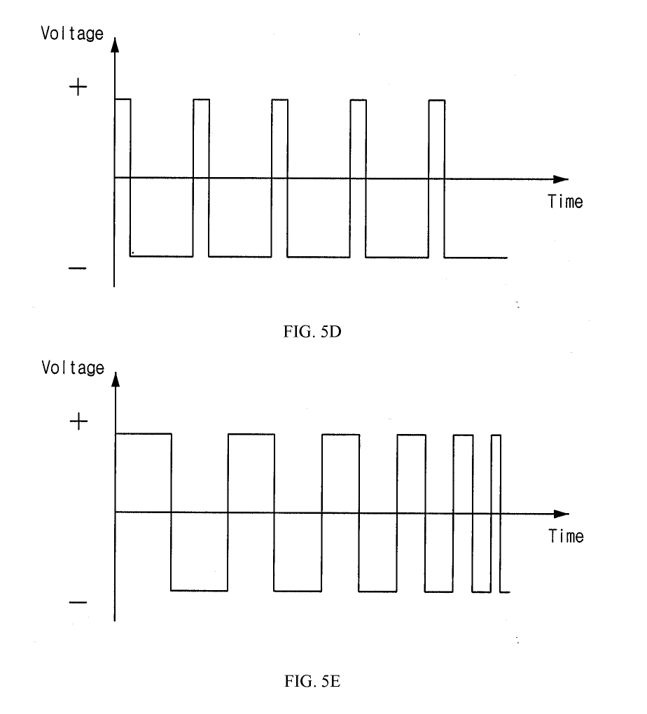

FIGS. 5A through 5I show various example voltage signals which may be applied to a vaporizing apparatus according to embodiments. However, the voltage signals in these figures are only exemplary, and the type of the voltage signal that may be applied to the vaporizing apparatus according to embodiments is not limited to those described or illustrated herein.

A voltage applied to a nozzle, an electrode and/or an interior wall in a vaporizing apparatus according to an embodiment may be a symmetric pulse signal as shown in FIGS. 5A through 5C. The pulse signal may have a duty cycle of about 50%, as shown in FIGS. 5A and 5B. Alternatively, the pulse signal may have a duty cycle smaller than 50% or larger than 50%. And, the pulse signal may have various frequency values. For example, the pulse signal shown in FIG. 5A has a higher frequency than the pulse signal shown in FIG. 5B.

The voltage applied to a vaporizing apparatus according to an embodiment may be an asymmetric pulse signal as shown in FIG. 5D. Alternatively, the voltage applied to the vaporizing apparatus may be pulse signal whose pulse width varies with time, as shown in FIG. 5E.

Depending on the type of the voltage signals applied to the vaporizing apparatus, the generated vapor may be charged to have a polarity. In this case, unless the vapor is neutralized, charges may accumulate on the film or semiconductor device where the vapor is used. To prevent this problem, the frequency, pulse width, polarity, duty cycle, etc. of the AC voltage signals may be controlled adequately so as to neutralize the charges of the vapor without an additional device.

Also, as seen from FIGS. 5F and 5G, the voltage applied to the vaporizing apparatus may be a pulse signal outputting a voltage of a positive or negative polarity only. Alternatively, the voltage applied to the vaporizing apparatus may be a DC voltage signal. For example, as shown in FIGS. 5H and FIG. 5I, the voltage applied to the vaporizing apparatus may be a DC voltage signal outputting a constant voltage of a positive or negative polarity.

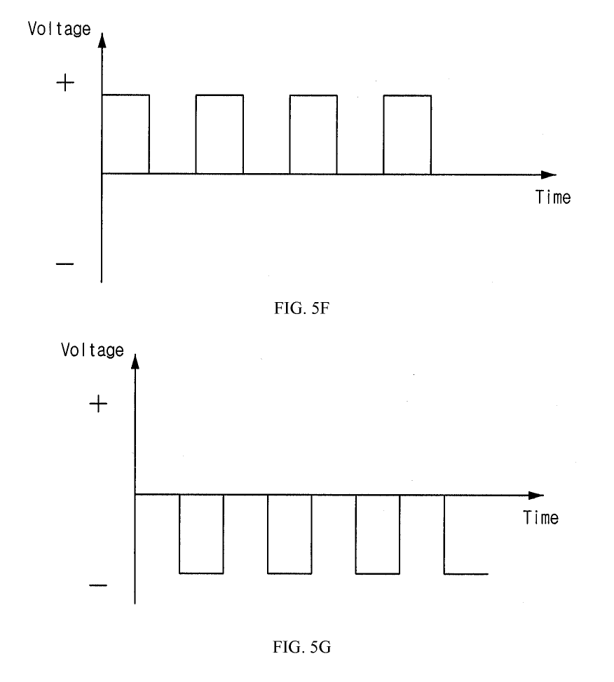

FIG. 6A is a block diagram of a vaporizing apparatus according to an embodiment. The vaporizing apparatus may include an MFC 610, a vaporizer 630, an LFM 612, a function generator 618, and a voltage generator 616. The configuration and function of the vaporizer 630 is similar to corresponding components in FIGS. 4A through 4D, and therefore, detailed description on the vaporizer 630 is omitted herein. The function generator 618 and the voltage generator 616 perform the same function as the voltage source described in the embodiments described above with reference to FIGS. 4A through 4D.

A carrier gas and a liquid may be supplied to the vaporizer 630 respectively through the MFC 610 and the LFM 612. The function generator 618 may generate various pulse-type signals. The voltage generator 616 may generate various voltage signals according to the signals from the function generator 618, and the generated voltage may be applied between a nozzle and an electrode of the vaporizer 630. Due to the applied voltage, charges are applied to the droplets of the liquid in the vaporizer 630, and the charged droplets may be converted into vapor by heating.

In an embodiment, the vaporizing apparatus further includes a charge neutralizer 620. The charge neutralizer 620 neutralizes the charges of the vapor generated in the vaporizer 630. For example, if the vapor has electrons, the charge neutralizer 620 may supply holes to the vapor. Conversely, if the vapor has vapor holes, the charge neutralizer 620 may supply electrons to the vapor.

FIG. 6B is a block diagram of a vaporizing apparatus according to another embodiment. The vaporizing apparatus may further include a vapor reservoir 622. The vapor generated in the vaporizer 630 and a carrier gas is temporarily stored in the vapor reservoir 622. When vapors of opposite polarity are generated in an alternating manner in the vaporizer 630, the generated vapors are mixed in the vapor reservoir 622 where the vapors of opposite polarity are neutralized. The vapor reservoir 622 may replace or be used in addition to the charge neutralizer described above with reference to FIG. 6A.

FIG. 6C is a block diagram of a vaporizing apparatus according to another embodiment. The vaporizing apparatus includes a feedback sensor 640 attached to or configured as part of a field-of-use device in which the vapor generated in the vaporizer 630 is used. The field-of-use device may be, but is not limited to, a vapor reservoir, a reactor, an injector or a nozzle. The feedback sensor 640 receives the vapor generated in the vaporizer 630 and transmits a feedback signal in response to the received vapor to a function generator 618. For example, the feedback signal may represent the polarity of the received vapor and/or the amount of charges contained in the vapor. By controlling the function generator 618 using the feedback signal, the polarity of the vapor output from the vaporizer 630 may be controlled as desired. Furthermore, a charge neutralizer 620 may be controlled using the feedback signal.

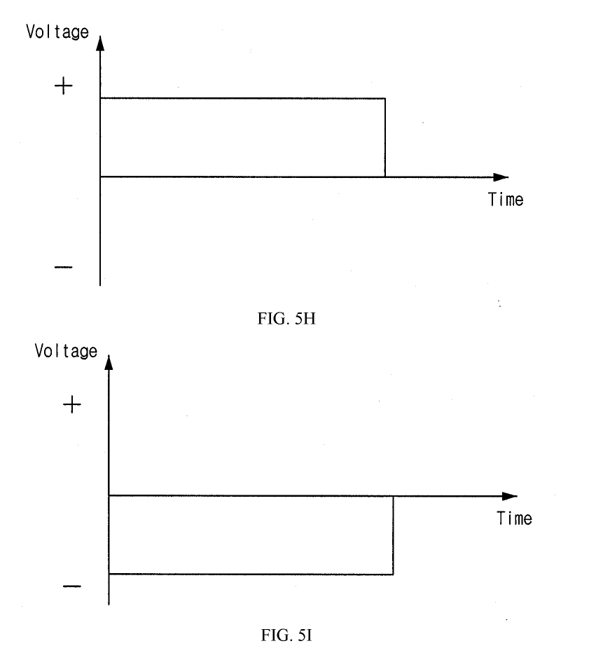

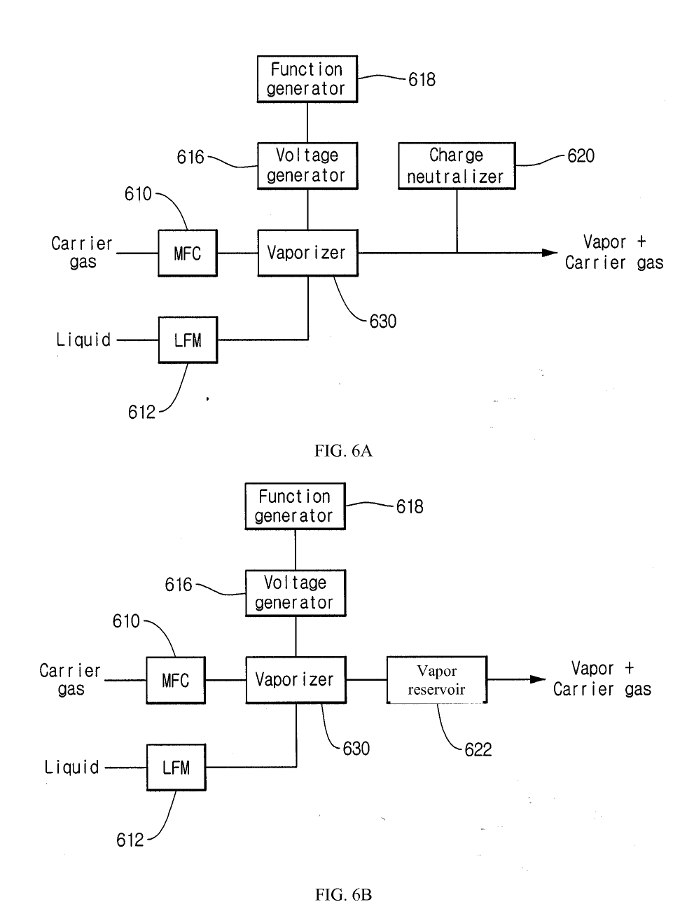

FIG. 7A is a diagram illustrating an example where vapor is not completely neutralized in a vaporizing apparatus according to an embodiment. The AC voltage signal of a positively and negatively alternating polarity are applied to droplets, and, as a result, positively charged droplets and negatively charged droplets are generated in an alternating manner. For example, the droplets generated at a plurality of consecutive time sections t₋₁, t₀ and t₊₁ is charged positively, negatively and positively, respectively. By vaporizing the charged droplets by applying heat thereto, positively charged vapor and negatively charged vapor are generated in an alternating manner.

In FIG. 7A, the vapors generated at respective time sections are represented by differently hashed areas. Differently hashed areas correspond to vapors charged with different polarity of the vapors. As seen in the figure, vapors of different polarity are generated at the plurality of consecutive time sections t₋₁, t₀ and t₊₁. At the portion where the positively charged vapor and the negatively charged vapor overlap, neutralized vapor may be generated. However, if the positively charged vapor and the negatively charged vapor are not completely mixed, charges may remain in the vapor. Also, if the quantity of the positively charged droplets is different from that of the negatively charged droplets, charges may remain in the vapor.

FIG. 7B is a diagram illustrating an example where vapor is completely neutralized in a vaporizing apparatus according to an embodiment. Negatively and positively charged droplets are generated at a plurality of consecutive time sections t₋₁, t₀ and t₊₁, respectively. By vaporizing the charged droplets by applying heat thereto, vapors having polarity corresponding to the respective time sections may be generated. By controlling parameters such as the frequency, pulse width, polarity, and duty cycle of the AC voltage signal applied to apply charges and/or by controlling the flow rate of the vapor, the negatively charged vapor may be completely mixed with the positively charged vapor, thereby neutralizing the charges contained in the vapor.

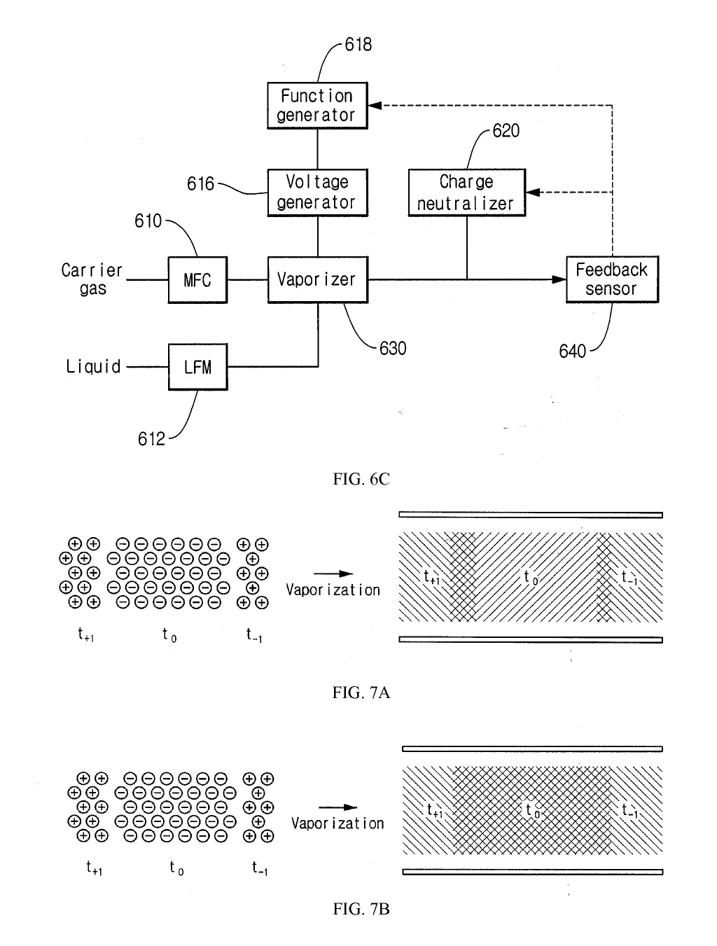

FIG. 8 is a schematic diagram illustrating an atomic layer deposition (ALD) device incorporating a vaporizing apparatus according to an embodiment. The ALD device may include, among other components, a vaporizing apparatus 1010 according to an embodiment coupled with a reactor module 1026. The vaporizing apparatus 1010 may include, among other components, an atomizer assembly 1012, a vaporizer assembly 1014, a voltage generator 1016, and a vapor reservoir 1018. The atomizer assembly 1012 and the vaporizer assembly 1014 respectively correspond to the atomizing stage and the vaporizing stage of the vaporizers described above with reference to FIGS. 4A through 4D.

A liquid precursor and a carrier gas may be injected into the vaporizing apparatus 1010. The carrier gas may be, but is not limited to, argon gas. In the vaporizing apparatus 1010, a vapor is generated from the liquid precursor. The generated vapor may be transferred to the reactor module 1026. By moving a substrate 1030 close to the reactor module 1026, a thin film may be formed on the substrate 1030 by the vapor of the precursor injected to the reactor module 1026. Residual vapor and carrier gas may be discharged through an exhaust portion 1022 formed at the reactor module 1026.

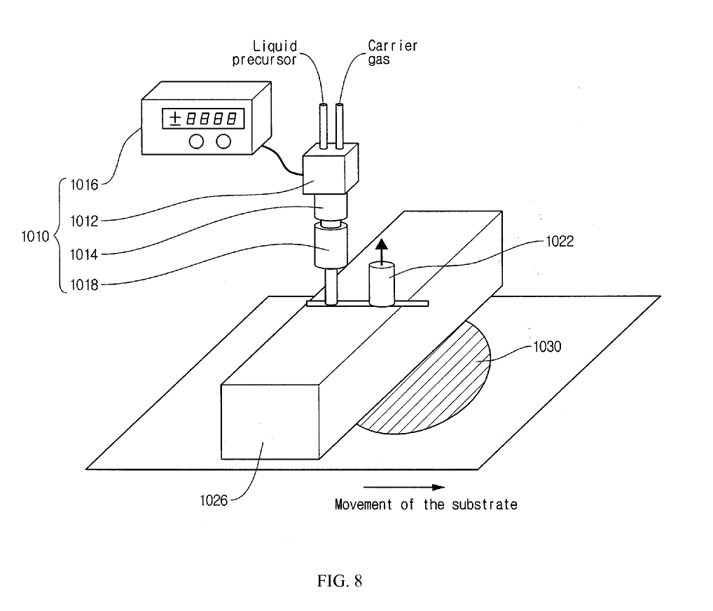

FIG. 9 is a schematic diagram illustrating another ALD device incorporating a vaporizing apparatus according to an embodiment. The ALD device may include a vaporizing apparatus 1100 coupled with an injector module 1110. The injector module 1110 may be disposed in a chamber 1180. The interior of the chamber 1180 may be maintained at low pressure by discharging gas using a pumping port 1170 and a vacuum gauge 1120. One or more substrates 1150 may be mounted on a susceptor 1140. The susceptor 1140 may be connected to a rotational motor 1130. As the susceptor 1140 rotates, the substrates 1150 pass below the injector module 1110, at which instance, the vapor of the precursor to the substrate 1150 is injected using the vaporizing apparatus 1100 and the injector module 1110 to form a thin film on the substrate 1150. Further, the ALD device may be equipped with devices for performing various other processes, such as a remote plasma device 1160 that generates plasma using a coil and a reactant gas.

FIGS. 8 and 9 show examples of using the vaporizing apparatus for thin film deposition. However, this is only exemplary, and the vaporizing apparatus may be utilized for other purposes and devices. For example, the vaporizing apparatus may be used to vaporize a polymer such as a photoresist in liquid state. By ejecting the polymer in vapor to the surface of the substrate from the vaporizing apparatus, the substrate may be coated with the polymer.

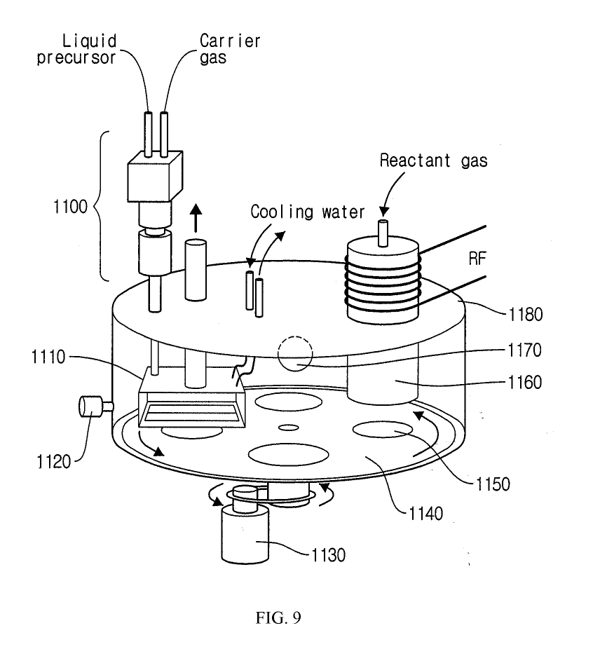

FIG. 10 is a flowchart illustrating a method of vaporizing liquid, according to one embodiment. First, liquid is injected 2010 into a nozzle. A voltage source generates 2020 a voltage signal to be applied to the nozzle. The liquid injected into the node is atomized 2030 into droplets using Venturi effect. The voltage signal generated at the voltage source is applied 2040 to the nozzle, thereby charging the droplets. The charged droplet is then vaporized 2050 by heating the droplets.

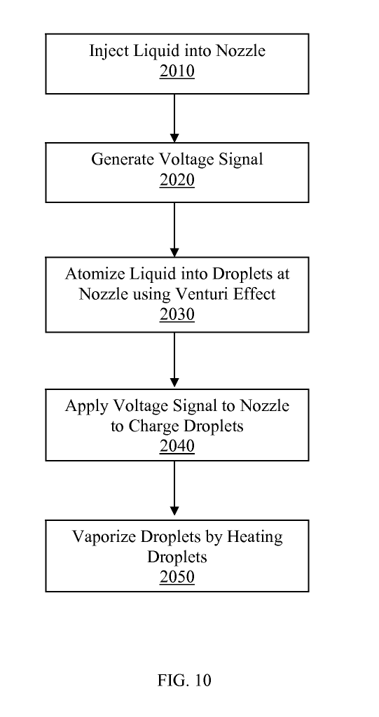

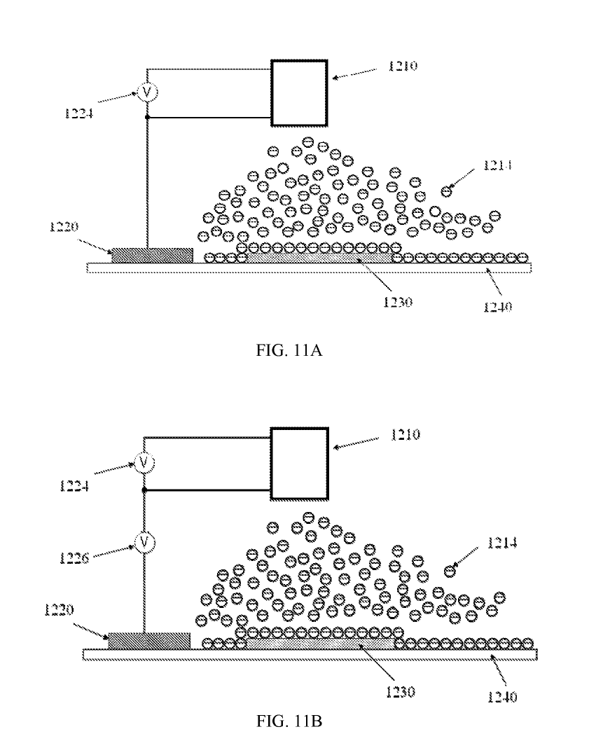

FIG. 11A is a schematic diagram illustrating an apparatus for selectively coating a substrate with charged droplets or vapor, according to embodiment. The apparatus of FIG. 11A may include, among other components, an ejection apparatus 1210 and a voltage source 1224. The voltage source 1224 is connected to the ejection apparatus 1210. The ejection apparatus 1210 may be embodied as the vaporizer 400A illustrated above in detail with reference to FIGS. 4A through 4D. Alternatively, the ejection apparatus 1210 may be embodied as an atomizer that omits the vaporizing stage 4100 from the vaporizer 400A to produce atomized droplets instead of vapor. The ejection apparatus 1210 ejects atomized or vaporized material 1214 onto a substrate 1240. The ejected materials 1214 may include, but is not limited to, photoresist and liquid polymer (e.g., polyimide).

A device 1230 such as a semiconductor device is provided on the substrate 1240. A shadow mask 1220 is placed between the ejection apparatus 1210 and the substrate 1240 to selectively coat areas of the substrate 1240 with atomized or vaporized material. For example, when manufacturing an OLED device, a layer needs to be selectively coated on the portion of the substrate. The shadow mask 1220 is used repeatedly for different substrates; and hence, the atomized or vaporized material tends to accumulate on or around the shadow mask 1220. Such accumulation of materials on or around the shadow mask 1220 leaves undesirable residues of the material on the substrate 1240 after the shadow mask 1220 is removed from the substrate 1240.

Hence, to reduce or prevent accumulation of the ejected materials on or around the shadow mask 1220, the shadow mask 1220 is connected to the voltage source 1224 to place the shadow mask 1220 at a voltage potential that repels the vapor or droplets 1214 from the shadow mask 1220. In the embodiment of FIG. 11A, the voltage source 1224 is used for applying charge to the vapor or droplets 1214 as well as applying charge to the shadow mask 1220. That is, the shadow mask 1220 is charged to have the same polarity as the charged droplets or vapor 1214. The repulsive force on the vapor or droplets 1214 exerted by the shadow mask 1220 reduces or prevents the vapor or droplets 1214 from landing on or around the shadow mask 1220. Since the shadow mask 1220 remains clear of ejected material, the shadow mask 1220 does not leave or leaves only a small amount of undesirable residue material on the substrate 1240.

Further, the portion of the substrate 1240 where the material should be coated may be charged with a polarity opposite to the charge of the droplets or vapor 1214 to attract the droplets or vapor to the desired portion in addition to or as an alternative to charging the shadow mask 1220 with the same polarity as the droplets or vapor 1214.

FIG. 11B is a schematic diagram illustrating an apparatus for selectively coating a substrate with charged droplets or vapor, according to another embodiment. The embodiment of FIG. 11B is essentially the same as the embodiment of FIG. 11A except that another voltage source 1226 is provided to charge the shadow mask 1220.

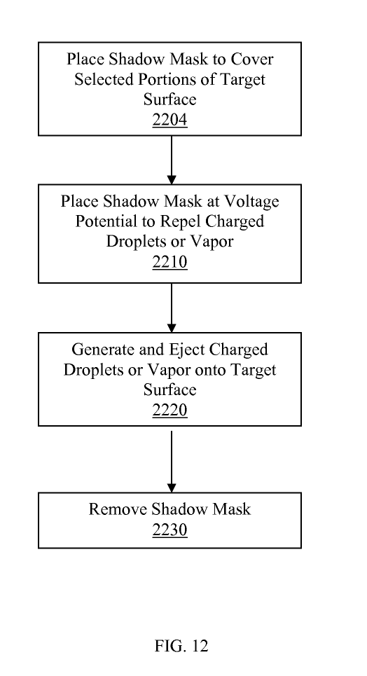

FIG. 12 is a flowchart illustrating a method of ejecting charged droplets onto a substrate using a shadow mask, according to one embodiment. First, a shadow mask is placed 2204 to cover selected portions of a target surface while exposing remaining portions of the target surface (e.g., substrate). The shadow mask is then placed 2210 at a voltage potential that repels charged droplets or vapor ejected from an ejection apparatus.

Then the ejection apparatus generates and ejects 2210 charged droplets or vapor of material onto the target surface. The charged droplets may be formed using a nozzle, as described above with reference to steps 2010 through 2040 in FIG. 10. The charged vapor may be formed by undergoing the additional step 2050 (in addition to steps 2010 through 2040) of FIG. 10. The shadow mask is removed 2230 after selected portions of the target surface are coated with the material. The steps and sequence of processes described in FIG. 12 are merely illustrative. For example, step 2210 may precede step 2204.

The vaporizing apparatus according to embodiments may be used in various fields including, but not limited to, devices that deposit organic or inorganic thin films by CVD and/or ALD processes, devices for supplying precursor materials that are deposited to form a thin film in organic light emitting diodes (OLED), devices that supply organic or inorganic precursor materials for encapsulation, and devices for supplying organic or inorganic polymer.

Although the present invention has been described above with respect to several embodiments, various modifications can be made within the scope of the present invention. Accordingly, the disclosure of the present invention is intended to be illustrative, but not limiting, of the scope of the invention, which is set forth in the following claims.

What is claimed is:

1. A vaporizing apparatus comprising:
a nozzle having one end connected to a source of liquid to receive liquid and another end configured to disperse the receive liquid into droplets;
a chamber connected to the other end of the nozzle to receive the droplets; and
a signal line between a voltage source and the nozzle to apply a voltage signal to the nozzle,
wherein the nozzle is configured to electrically charge the droplets responsive to receiving the voltage signal via the signal line.

2. The vaporizing apparatus of claim 1, further comprising an electrode within the chamber electrically isolated from the node, a first voltage applied across the electrode and the nozzle.

3. The vaporizing apparatus of claim 2, wherein the voltage source a second voltage across the nozzle and an interior wall of the chamber.

4. The vaporizing apparatus of claim 2, wherein the voltage source applies the second voltage across the electrode and an interior wall of the chamber.

5. The vaporizing apparatus of claim 1, wherein the voltage source applies a DC signal or an AC signal to the nozzle.

6. The vaporizing apparatus of claim 5, wherein a frequency, pulse width, polarity and duty cycle of the AC signal is determined based on a flow rate of the liquid into the nozzle and a size of the chamber.

7. The vaporizing apparatus of claim 2, wherein the electrode is disposed at an outlet of the chamber located opposite to the nozzle.

8. The vaporizing apparatus of claim 1, further comprising a heater for generating vapor by applying heat to the droplets.

9. The vaporizing apparatus of claim 8, further comprising a charge neutralizer connected to an outlet of the chamber for neutralizing charges contained in the vapor.

10. The vaporizing apparatus of claim 8, further comprising a vapor reservoir connected to an outlet of the chamber for storing the vapor discharged from the chamber.

11. The vaporizing apparatus of claim 8, further comprising a feedback sensor configured to sense a polarity of the vapor discharged from the chamber, and send a feedback signal indicative of the polarity to the voltage source.

12. A method of vaporizing a liquid, comprising:
injecting a liquid into one end of a nozzle from a source of the liquid;
generating a voltage signal at a voltage source;
generating droplets of a liquid at the other end of the nozzle by dispersing the liquid into a chamber; and
applying the voltage signal to the nozzle via a signal line to electrically charge the droplets.

13. The vaporizing method of claim 14, further comprising applying a first voltage across the nozzle and an electrode.

14. The vaporizing method of claim 13, further comprising a second voltage across the nozzle and an interior wall of the chamber.

15. The vaporizing method of claim 12, wherein the voltage signal is a DC signal or an AC signal.

16. The vaporizing method of claim 12, further comprising heating the droplets to generate vapor.

17. The vaporizing method of claim 16, further comprising controlling a polarity of the vapor by controlling a flow rate of the liquid through the nozzle.

18. The vaporizing method of claim 16, further comprising neutralizing charges of the vapor.

19. The vaporizing method of claim 14, further comprising:
generating a feedback signal at a sensor indicative of a polarity of the vapor; and
controlling the voltage signal based on the feedback signal.

20. The vaporizing method of claim 16, further comprising discharging the vapor to a surface of a substrate to form a layer on the surface of the substrate, wherein the vapor is electrically charged to selectively coat on the surface of the substrate depending on a polarity of the surface.

21. An apparatus for coating a target surface, comprising:
an ejection apparatus for ejecting charged droplets or vapor of material onto a target surface;
a shadow mask placed between the ejection apparatus and the target surface to cover selective portions of the target surface, wherein the shadow mask is placed at a voltage potential to repel the charged droplets or vapor; and
at least one voltage source for charging the shadow mask and the droplets or vapor of material.

22. The apparatus of claim 21, wherein the ejection apparatus comprises a nozzle having one end connected to a source of liquid to receive liquid and another end configured to disperse the receive liquid into droplets.

23. The apparatus of claim 21, wherein the ejected material comprises at least one of photoresist and liquid polymer.

24. A method for coating a target surface, comprising:
placing a shadow mask to cover a selected portion of the target surface;
placing shadow mask at a voltage potential by connecting the shadow mask to a voltage source; and
ejecting, onto the target surface, droplets or vapor of material charged with a polarity to receive repulsive force from the shadow mask.

25. The method of claim 24, further comprising:
injecting a liquid into one end of a nozzle from a source of the liquid;
generating a voltage signal at a voltage source;
generating droplets of a liquid at the other end of the nozzle by dispersing the liquid into a chamber; and
applying the voltage signal to the nozzle via a signal line to electrically charge the droplets.

26. The method of claim 24, wherein the ejected material comprises at least one of photoresist and liquid polymer.
